(19) United States
(12) Patent Application Publication
(10) Pub. No.: US 2016/0017083 A1
(43) Pub. Date: Jan. 21, 2016

(54) MODIFIED NOVOLAC PHENOL RESIN, RESIST MATERIAL, COATING FILM, AND RESIST PERMANENT FILM

(71) Applicant: DIC CORPORATION, Tokyo (JP)

(72) Inventors: Tomoyuki Imada, Ichihara-shi (JP); Takakazu Kage, Ichihara-shi (JP)

(21) Appl. No.: 14/773,769

(22) PCT Filed: Jan. 21, 2014
(86) PCT No.: PCT/JP2014/051073

§ 371 Date: Sep. 9, 2015

(30) Foreign Application Priority Data
Mar. 14, 2013 (JP) 2013-051790

(51) Int. Cl. C08G 8/30; G03F 7/038; C08G 8/28

(52) U.S. Cl. CPC C08G 8/30; C08G 8/28; G03F 7/038

(57) ABSTRACT

The present invention provides a modified novolac phenol resin having excellent developability and heat resistance, a method for producing the same, a photosensitive composition, a resist material, and a permanent film. The modified novolac phenol resin has a molecular structure in which hydrogen atoms of phenolic hydroxyl groups possessed by a novolac phenol resin (C) are partially or entirely substituted by acid dissociable groups, the novolac phenol resin (C) being produced by condensing an aromatic compound (A) represented by structural formula (1) below with an aldehyde compound (B).

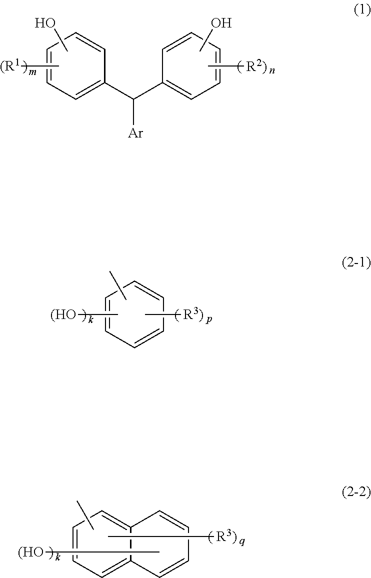

### TECHNICAL FIELD

The present invention relates to a modified novolac phenol resin having excellent developability and heat resistance and a resist material, a coating film, and a resist permanent film each using the phenol resin.

### BACKGROUND ART

Positive photoresists using an alkali-soluble resin and a photosensitizer such as a 1,2-naphthoquinone diazide compound or the like are known as resists used for manufacturing semiconductors such as IC, LSI, and the like, manufacturing display devices such as LCD and like, and manufacturing a printing original plate. A positive photoresist composition using as the alkali-soluble resin a mixture containing a m-cresol novolac resin and p-cresol novolac resin has been proposed (for example, refer to Patent Literature 1).

The positive photoresist composition described in Patent Literature 1 has been developed for the purpose of improving the developability such as sensitivity, but with recent increasing integration of semiconductors, patterns have tended to be further thinned, and more excellent sensitivity has been demanded. However, the positive photoresist composition described in Patent Literature 1 has the problem of failing to achieve satisfactory sensitivity corresponding to thinning. Further, various heat treatments are performed in a process for manufacturing semiconductors or the like, and thus higher heat resistance is also required. However, the positive photoresist composition described in Patent Literature 1 has a problem of unsatisfactory heat resistance.

Also, a phenol resin for photoresists, which is produced by reacting p-cresol or the like with aromatic aldehyde and then adding and reacting a phenol and formaldehyde to and with the reaction product under an acid catalyst has been proposed as having excellent sensitivity and high heat resistance (for example, refer to Patent Literature 2). The phenol resin for photoresists is improved in heat resistance as compared with usual ones but cannot satisfactorily comply with the recent requirement level for high heat resistance.

Further, a phenol resin for photoresists, which is produced by reacting a phenol such as m-cresol, p-cresol, 2,3-xylenol, or the like with aromatic aldehyde and then adding and reacting formaldehyde to and with the reaction product under an acid catalyst has been proposed as having excellent sensitivity and high heat resistance (for example, refer to Patent Literature 3). The phenol resin for photoresists is improved in sensitivity as compared with usual ones but cannot satisfactorily comply with the recent requirement level for high heat resistance.

In addition, there is a problem that design for improving alkali solubility in order to improve sensitivity of a novolac resin, which is an alkali soluble resin, decreases heat resistance, while design for improving heat resistance decreases sensitivity, thereby causing difficulty in satisfying both the high levels of sensitivity and heat resistance. Therefore, a material satisfying both the high levels of sensitivity and heat resistance is required.

A chemically amplified resist composition containing a compound in which a phenolic hydroxyl group possessed by a phenolic compound such as a novolac resin or the like is protected by an acid dissociation-type protecting group is known as a method for providing a material satisfying both the high levels of sensitivity and heat resistance. The chemically amplified resist composition of, for example, a positive type, is a radiation-sensitive composition containing a resin which is imparted with a dissolution suppressing effect by introducing a substituent, that is deprotected by an acid function, into an alkali developer-soluble resin and a compound (hereinafter referred to as a “photoacid generator”) which generates an acid by irradiation with light or radiation such as electron beams or the like. When the composition is irradiated with light or electron beams, an acid is produced from the photoacid generator, and the acid deprotects the substituent, which imparts the dissolution suppressing effect, by heating (PEB) after light exposure. As a result, an exposed portion is made alkali soluble, and thus a positive resist pattern is produced by treatment with an alkali developer. In this case, the acid functions as a catalyst and exhibits the effect in a very small amount. Also, the movement of the acid is activated by PEB, and chemical reaction is accelerated in a chain reaction, thereby improving sensitivity.

A known example of the chemically amplified resist composition is a composition containing a resin in which phenolic hydroxyl groups possessed by a novolac resin, which is produced by condensation reaction of an aromatic hydroxy compound with aldehydes including at least formaldehyde and hydroxyl group-substituted aromatic aldehyde, are partially protected by acid-dissociable dissolution suppressing groups (for example, refer to Patent Literature 4). However, a resist material using the compound disclosed in Patent Literature 4 has the problem of significantly degrading heat resistance by disappearance of hydrogen bond parts due to introduction of protecting groups in the compound.

### CITATION LIST

### Patent Literature

PTL 1: Japanese Unexamined Patent Application Publication No. 2-55359
PTL 2: Japanese Unexamined Patent Application Publication No. 2008-88197
PTL 3: Japanese Unexamined Patent Application Publication No. 9-90626
PTL 4: Japanese Unexamined Patent Application Publication No. 2005-300820

### SUMMARY OF INVENTION

### Technical Problem

A problem to be solved by the present invention is to provide a modified novolac phenol resin satisfying both the high levels of sensitivity and heat resistance which are so far difficult to satisfy and having high sensitivity and heat resistance, and provide a resist material, a coating film, and a resist permanent film each using the phenol resin.

### Solution to Problem

As a result of repeated keen studies, the inventors found that a modified novolac phenol resin produced by modifying phenolic hydroxyl groups of a novolac phenol resin (C) with acid dissociable groups has both the high levels of sensitivity and heat resistance, the novolac phenol resin (C) being produced by using an aromatic compound (A) represented by structural formula (1) below

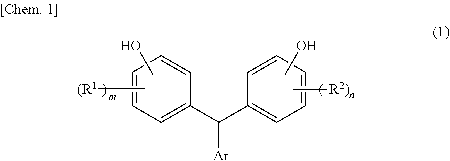

[in the formula, Ar is a structural moiety represented by structural formula (2-1) or (2-2) below

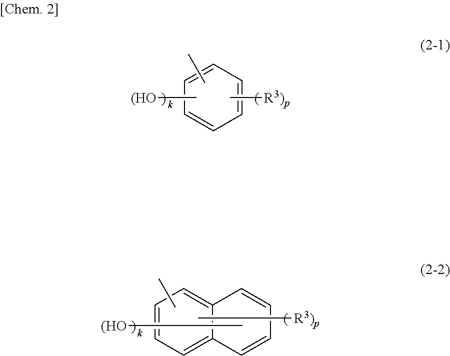

(in the formula, k is an integer of 0 to 2, p is an integer of 1 to 5, q is an integer of 1 to 7, and R³ is any one of a hydrogen atom, an alkyl group, an alkoxy group, an aryl group, an aralkyl group, and a halogen atom), R¹ and R² are each any one of an alkyl group, an alkoxy group, an aryl group, an aralkyl group, and a halogen atom, and m and n are each an integer of 1 to 4], leading to the achievement of the present invention.

That is, the present invention relates to a modified novolac phenol resin having a molecular structure in which hydrogen atoms of phenolic hydroxyl groups possessed by a novolac phenol resin (C) are partially or entirely substituted by acid dissociable groups, the novolac phenol resin (C) being produced by condensing an aromatic compound (A) represented by structural formula (1) below with an aldehyde compound (B),

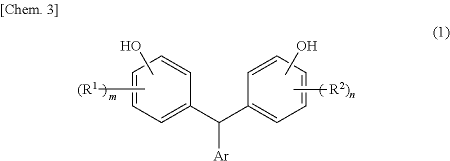

[in the formula, Ar is a structural moiety represented by structural formula (2-1) or (2-2) below

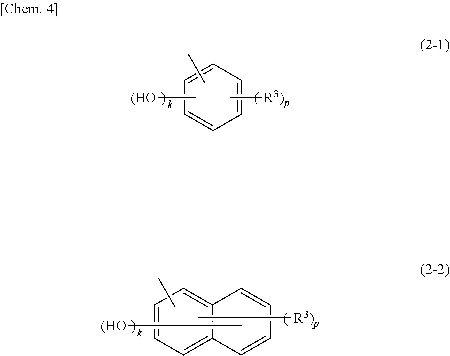

(in the formula, k is an integer of 0 to 2, p is an integer of 1 to 5, q is an integer of 1 to 7, and R³ is any one of a hydrogen atom, an alkyl group, an alkoxy group, an aryl group, an aralkyl group, and a halogen atom), R¹ and R² are each any one of an alkyl group, an alkoxy group, an aryl group, an aralkyl group, and a halogen atom, and m and n are each an integer of 1 to 4].

Further, the present invention relates to a method for producing a modified novolac phenol resin, the method including reacting a phenol compound (a1) having any one of an alkyl group, an alkoxy group, an aryl group, an aralkyl group, and a halogen atom as a substituent on an aromatic nucleus with an aromatic aldehyde (a2) to produce an aromatic compound (A), condensation-reacting the resultant aromatic compound (A) with an aldehyde compound (B), and then reacting the resultant novolac phenol resin (C) with a compound represented by any one of structural formulae (3-1) to (3-8) below,

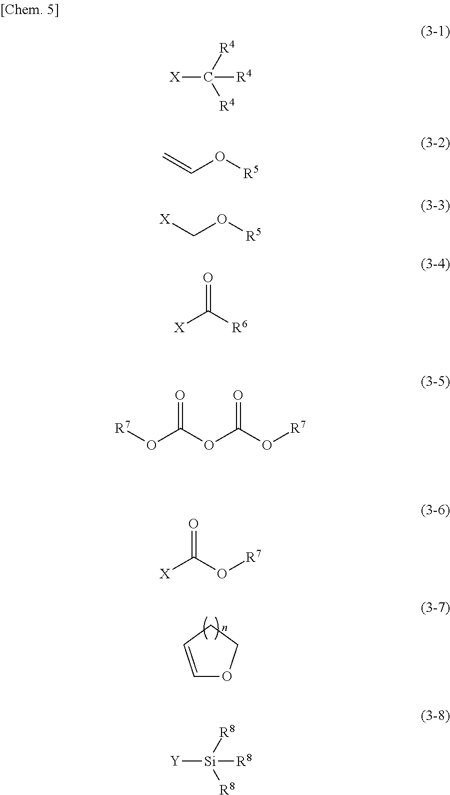

(in the formulae, X represents a halogen atom, Y represents a halogen atom or a trifluoromethanesulfonyl group, R⁴ to R⁸ each independently represent an alkyl group having 1 to 6 carbon atoms or a phenyl group, and n is 1 or 2).

Further, the present invention relates to a photosensitive composition containing the modified novolac phenol resin and a photoacid generator.

Further, the present invention relates to a resist material including the photosensitive composition.

Further, the present invention relates to a coating film including the photosensitive composition.

Further, the present invention relates to a resist permanent film including the resist material.

### Advantageous Effects of Invention

A modified novolac phenol resin of the present invention satisfies both high levels of sensitivity and heat resistance which are so far difficult to satisfy and thus can be preferably used for positive photoresist application used for manufacturing semiconductors such as IC, LSI, and the like, manufacturing display devices such as LCD and the like, and manufacturing printing original plates, in which thinner patterns are formed.

### BRIEF DESCRIPTION OF DRAWINGS

FIG. 1 is a GPC chart of a modified novolac phenol resin (1) produced in Example 1.

### DESCRIPTION OF EMBODIMENTS

A modified novolac phenol resin of the present invention has a molecular structure in which hydrogen atoms of phenolic hydroxyl groups possessed by a novolac phenol resin (C) are partially or entirely substituted by acid dissociable groups, the novolac phenol resin (C) being produced by condensing an aromatic compound (A) represented by structural formula (1) below with an aldehyde compound (B),

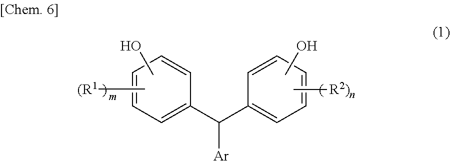

[in the formula, Ar is a structural moiety represented by structural formula (2-1) or (2-2) below

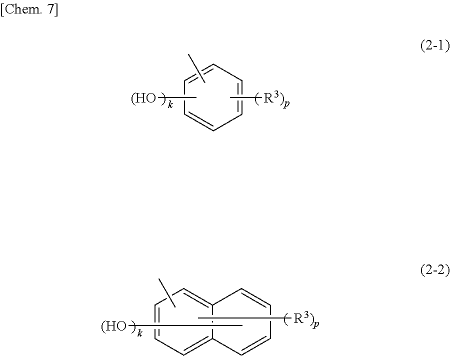

(in the formula, k is an integer of 0 to 2, p is an integer of 1 to 5, q is an integer of 1 to 7, and R³ is any one of a hydrogen atom, an alkyl group, an alkoxy group, an aryl group, an aralkyl group, and a halogen atom), R¹ and R² are each any one of an alkyl group, an alkoxy group, an aryl group, an aralkyl group, and a halogen atom, and m and n are each an integer of 1 to 4].

Since a triarylmethane-type structure possessed by the aromatic compound (A) has very high rigidity and contains aromatic rings at a high density, and thus the modified novolac phenol resin of the present invention produced by using the aromatic compound (A) has very high heat resistance. Also, the novolac phenol resin (C) produced by using the aromatic compound (A) has a high hydroxyl group content as compared with general phenol novolac resins and has excellent hydroxyl group reactivity, and thus the modified novolac phenol resin of the present invention produced by using the novolac phenol resin (C) has excellent developability as well as high heat resistance.

In the structural formula (1) representing the aromatic compound (A), R¹ and R² are each any one of an alkyl group, an alkoxy group, an aryl group, an aralkyl group, and a halogen atom. Examples of the alkyl group include a methyl group, an ethyl group, a propyl group, a butyl group, a pentyl group, a hexyl group, a cyclohexyl group, and the like. Examples of the alkoxy group include a methoxy group, an ethoxy group, a propyloxy group, a butoxy group, a pentyloxy group, a hexyloxy group, a cyclohexyloxy group, and the like. Examples of the aryl group include a phenyl group, a hydroxyphenyl group, a dihydroxyphenyl group, a hydroxyalkoxyphenyl group, an alkoxyphenyl group, a tolyl group, a xylyl group, a naphthyl group, a hydroxynaphthyl group, a dihydroxynaphthyl group, and the like. Examples of the aralkyl group include a phenylmethyl group, a hydroxyphenylmethyl group, a dihydroxyphenylmethyl group, a tolylmethyl group, a xylylmethyl group, a naphthylmethyl group, a hydroxynaphthylmethyl group, a dihydroxynaphthylmethyl group, a phenylethyl group, a hydroxyphenylethyl group, a dihydroxyphenylethyl group, a tolylethyl group, a xylylethyl group, a naphthylethyl group, a hydroxynaphthylethyl group, a dihydroxynaphthylethyl group, and the like. Examples of the halogen atom include a fluorine atom, a chlorine atom, and a bromine atom.

Among these, R¹ and R² are each preferably an alkyl group because the modified novolac phenol resin having excellent balance between heat resistance and developability can be produced, and a methyl group is particularly preferred because of high heat resistance of the compound due to high rigidity imparted to a molecule by suppression of molecular motion, an excellent electron donating property to an aromatic nucleus, and easy industrial availability.

In the structural formula (1), m and n are each an integer of 1 to 4, and m and n are each preferably 1 or 2 because the modified novolac phenol resin having excellent balance between heat resistance and developability can be produced.

The bond positions of two phenolic hydroxyl groups in the structural formula (1) are preferably the para-positions to a methine group which links three aromatic rings together because the modified novolac phenol resin having excellent heat resistance can be produced.

In the structural formula (1), Ar is a structural moiety represented by the structural formula (2-1) or (2-2). In particular, the structural moiety represented by the structural formula (2-1) is preferred because the modified novolac phenol resin having excellent developability can be produced.

In the structural formulae (2-1) and (2-2), R³ is any one of a hydrogen atom, an alkyl group, an alkoxy group, an aryl group, an aralkyl group, and a halogen atom. Examples of the alkyl group include a methyl group, an ethyl group, a propyl group, a butyl group, a pentyl group, a hexyl group, a cyclohexyl group, and the like. Examples of the alkoxy group include a methoxy group, an ethoxy group, a propyloxy group, a butoxy group, a pentyloxy group, a hexyloxy group, a cyclohexyloxy group, and the like. Examples of the aryl group include a phenyl group, a hydroxyphenyl group, a dihydroxyphenyl group, a hydroxyalkoxyphenyl group, an alkoxyphenyl group, a tolyl group, a xylyl group, a naphthyl group, a hydroxynaphthyl group, a dihydroxynaphthyl group, and the like. Examples of the aralkyl group include a phenylmethyl group, a hydroxyphenylmethyl group, a dihydroxyphenylmethyl group, a tolylmethyl group, a xylylmethyl group, a naphthylmethyl group, a hydroxynaphthylmethyl group, a dihydroxynaphthylmethyl group, a phenylethyl group, a hydroxyphenylethyl group, a dihydroxyphenylethyl group, a tolylethyl group, a xylylethyl group, a naphthylethyl group, a hydroxynaphthylethyl group, a dihydroxynaphthylethyl group, and the like. Examples of the halogen atom include a fluorine atom, a chlorine atom, and a bromine atom.

Among these, R³ is preferably a hydrogen atom or an alkyl group because the modified novolac phenol resin having excellent balance between heat resistance and developability can be produced, and a hydrogen atom is more preferred because the aromatic compound (A) can be easily produced.

Specifically, the aromatic compound (A) represented by the structural formula (1) is a compound having a molecular structure represented by any one of structural formulae (1-1) to (1-16) below.

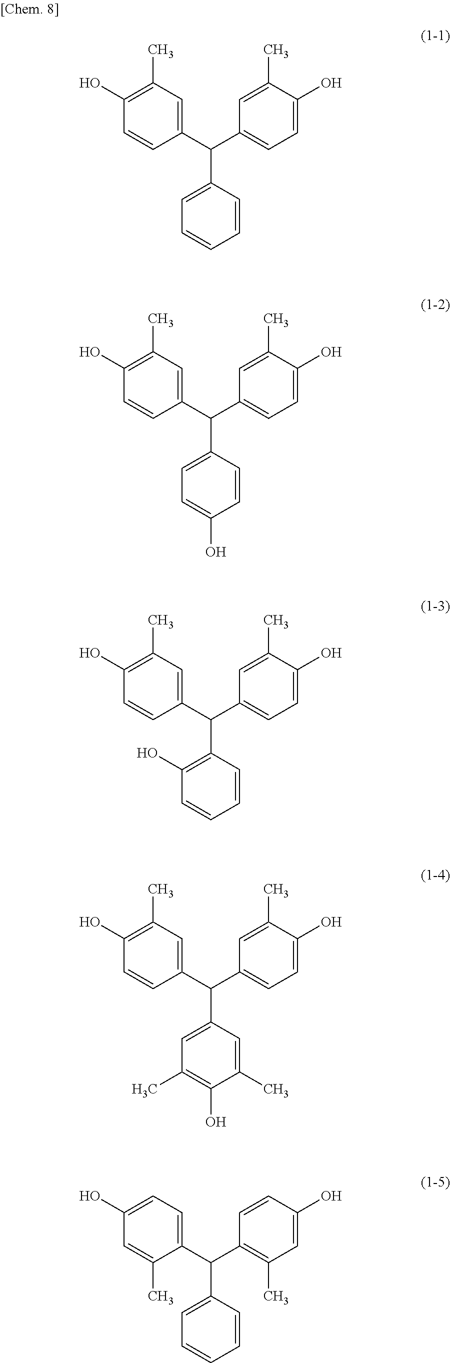 [SMILES: Cc1cc(C(c2ccccc2)c2ccc(O)c(C)c2)ccc1O ; Cc1cc(C(c2ccc(O)cc2)c2ccc(O)c(C)c2)ccc1O ; Cc1cc(C(c2ccc(O)c(C)c2)c2ccccc2O)ccc1O ; Cc1cc(C(c2ccc(O)c(C)c2)c2cc(C)c(O)c(C)c2)ccc1O ; Cc1cc(O)ccc1C(c1ccccc1)c1ccc(O)cc1C]

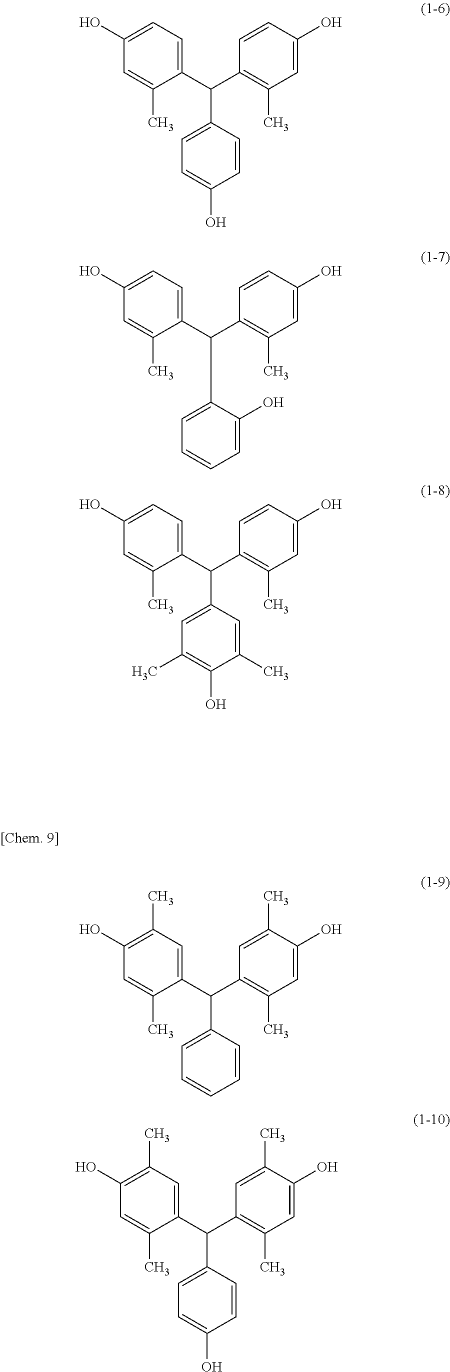 [SMILES: Cc1cc(O)ccc1C(c1ccc(O)cc1)c1ccc(O)cc1C ; Cc1cc(O)ccc1C(c1ccc(O)cc1C)c1ccccc1O ; Cc1cc(O)ccc1C(c1cc(C)c(O)c(C)c1)c1ccc(O)cc1C ; Cc1cc(C(c2ccccc2)c2cc(C)c(O)cc2C)c(C)cc1O ; Cc1cc(C(c2ccc(O)cc2)c2cc(C)c(O)cc2C)c(C)cc1O]

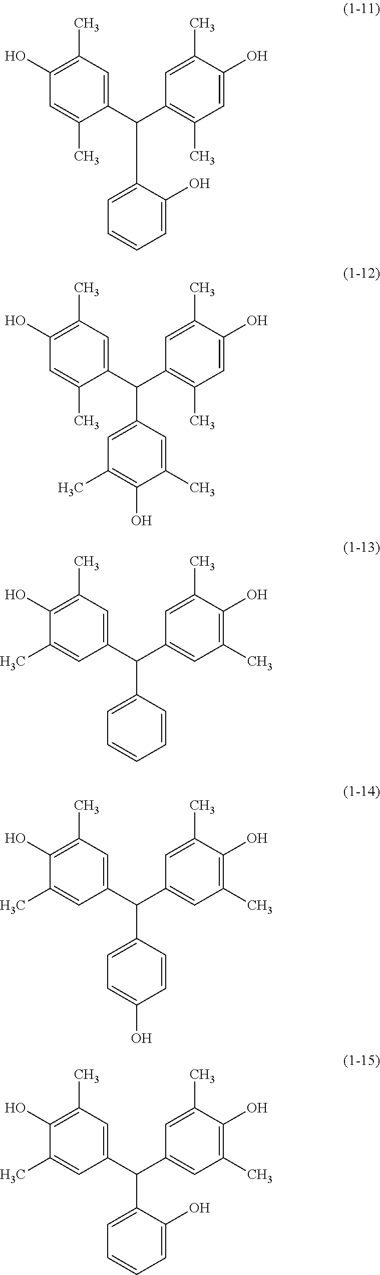 [SMILES: Cc1cc(C(c2cc(C)c(O)cc2C)c2ccccc2O)c(C)cc1O ; Cc1cc(C(c2cc(C)c(O)c(C)c2)c2cc(C)c(O)cc2C)c(C)cc1O ; Cc1cc(C(c2ccccc2)c2cc(C)c(O)c(C)c2)cc(C)c1O ; Cc1cc(C(c2ccc(O)cc2)c2cc(C)c(O)c(C)c2)cc(C)c1O ; Cc1cc(C(c2cc(C)c(O)c(C)c2)c2ccccc2O)cc(C)c1O]

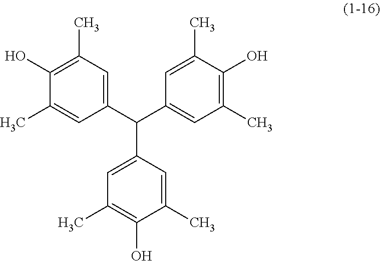 [SMILES: Cc1cc(C(c2cc(C)c(O)c(C)c2)c2cc(C)c(O)c(C)c2)cc(C)c1O]

Compounds represented by the structural formula (1) may be used alone or in combination of two or more as the aromatic compound (A) used for producing the modified novolac phenol resin of the present invention. In particular, any one of the aromatic compounds represented by the structural formula (1) is preferably used in an amount of 50% by mass or more and more preferably 80% by mass or more because the modified novolac phenol resin having excellent heat resistance can be produced.

The aromatic compound (A) can be produced by, for example, a method of reacting a phenol compound (a1) with an aromatic aldehyde (a2) in the presence of an acid catalyst.

The phenol compound (a1) is a compound in which the hydrogen atoms bonded to an aromatic ring of phenol are partially or entirely substituted by any one of an alkyl group, an alkoxy group, an aryl group, an aralkyl group, and a halogen atom. Examples of the alkyl group include a methyl group, an ethyl group, a propyl group, a butyl group, a pentyl group, a hexyl group, a cyclohexyl group, and the like. Examples of the alkoxy group include a methoxy group, an ethoxy group, a propyloxy group, a butoxy group, a pentyloxy group, a hexyloxy group, a cyclohexyloxy group, and the like. Examples of the aryl group include a phenyl group, a hydroxyphenyl group, a dihydroxyphenyl group, a hydroxyalkoxyphenyl group, an alkoxyphenyl group, a tolyl group, a xylyl group, a naphthyl group, a hydroxynaphthyl group, a dihydroxynaphthyl group, and the like. Examples of the aralkyl group include a phenylmethyl group, a hydroxyphenylmethyl group, a dihydroxyphenylmethyl group, a tolylmethyl group, a xylylmethyl group, a naphthylmethyl group, a hydroxynaphthylmethyl group, a dihydroxynaphthylmethyl group, a phenylethyl group, a hydroxyphenylethyl group, a dihydroxyphenylethyl group, a tolylethyl group, a xylylethyl group, a naphthylethyl group, a hydroxynaphthylethyl group, a dihydroxynaphthylethyl group, and the like. Examples of the halogen atom include a fluorine atom, a chlorine atom, and a bromine atom. The phenol compound (a1) may be singly as one type or as two or more types in any combination.

In particular, alkyl-substituted phenol is preferred because the modified novolac phenol resin having excellent balance between heat resistance and developability can be produced. Examples thereof include o-cresol, m-cresol, p-cresol, 2,5-xylenol, 3,5-xylenol, 3,4-xylenol, 2,4-xylenol, 2,6-xylenol, 2,3,5-trimethylphenol, 2,3,6-trimethylphenol, and the like. Among these, 2,5-xylenol and 2,6-xylenol are particularly preferred because the modified novolac phenol resin can be produced.

Examples of the aromatic aldehyde (a2) include benzaldehyde; hydroxybenzaldehyde compounds such as salicyl aldehyde, m-hydroxybenzaldehyde, p-hydroxybenzaldehyde, and the like; dihydroxybenzaldehyde such as 2,4-dihydroxybenzaldehyde, 3,4-dihydroxybenzaldehyde, and the like; vanillin compounds such as vanillin, ortho-vanillin, isovanillin, ethyl vanillin, and the like; and hydroxynaphthaldehyde compounds such as 2-hydroxy-1-naphthaldehyde, 6-hydroxy-2-naphthaldehyde, and the like. These may be used alone or in combination or two or more.

Among these aromatic aldehydes (a2), hydroxybenzaldehyde compounds or hydroxynaphthaldehyde compounds are preferred, and p-hydroxybenzaldehyde is particularly preferred because the modified novolac phenol resin having excellent balance between heat resistance and developability can be produced.

The reaction molar ratio [(a1)/(a2)] of the phenol compound (a1) to the aromatic aldehyde (a2) is preferably within a range of 1/0.2 to 1/0.5 and more preferably within a range of 1/0.25 to 1/0.45 because the intended aromatic compound (A) can be produced in high yield and high purity.

Examples of the acid catalyst used for reaction between the phenol compound (a1) and the aromatic aldehyde (a2) include acetic acid, oxalic acid, sulfuric acid, hydrochloric acid, phenolsulfonic acid, para-toluenesulfonic acid, zinc acetate, manganese acetate, and the like. These acid catalysts may be used alone or in combination of two or more. Among these, sulfuric acid and para-toluenesulfonic acid are preferred because of excellent catalytic activity.

If required, the reaction between the phenol compound (a1) and the aromatic aldehyde (a2) may be performed in an organic solvent. Examples of the solvent used include monoalcohols such as methanol, ethanol, propanol, and the like; polyols such as ethylene glycol, 1,2-propanediol, 1,3-propanediol, 1,4-butanediol, 1,5-pentanediol, 1,6-hexanediol, 1,7-heptanediol, 1,8-octanediol, 1,9-nonanediol, trimethylene glycol, diethylene glycol, polyethylene glycol, glycerin, and the like; glycol ethers such as 2-ethoxyethanol, ethylene glycol monomethyl ether, ethylene glycol monoethyl ether, ethylene glycol monopropyl ether, ethylene glycol monobutyl ether, ethylene glycol monopentyl ether, ethylene glycol dimethyl ether, ethylene glycol ethyl methyl ether, ethylene glycol monophenyl ether, and the like; cyclic ethers such as 1,3-dioxaene, 1,4-dioxane, tetrahydrofuran, and the like; glycol esters such as ethylene glycol acetate and the like; and ketones such as acetone, methyl ethyl ketone, methyl isobutyl ketone, and the like. These solvents may be used alone or as a mixed solvent of two or more. Among these, 2-ethoxyethanol is preferred because of excellent solubility of the resultant aromatic compound (A).

The reaction between the phenol compound (a1) and the aromatic aldehyde (a2) is performed, for example, within a temperature range of 60° C. to 140° C. over a time of 0.5 to 100 hours.

After the completion of reaction, the unreacted phenol compound (a1) and aromatic aldehyde (a2) and the acid catalyst used are removed by, for example, a method in which the precipitate produced by pouring the reaction product into a poor solvent (S1) for the aromatic compound (A) is filtered off, and then the resultant precipitate is re-dissolved in a solvent (S2) in which the aromatic compound (A) has high solubility and which is miscible with the poor solvent (S1), thereby permitting the production of the purified aromatic compound (A).

Also, when the reaction between the phenol compound (a1) and the aromatic aldehyde (a2) is performed in an aromatic hydrocarbon solvent such as toluene, xylene, or the like, the aromatic compound (A) is dissolved in the aromatic hydrocarbon solvent by heating the reaction product to 80° C. or more and then cooled as it is, thereby enabling precipitation of crystals of the aromatic compound (A).

The purity of the aromatic compound (A) calculated from a GPC chart diagram is preferably 90% or more, more preferably 94% or more, and particularly preferably 98% or more because the modified novolac phenol resin excellent in both the developability and heat resistance can be produced. The purity of the aromatic compound (A) can be determined from an area ratio in a gel permeation chromatography (GPC) chart.

In the present invention, GPC measurement conditions are as follows.

### [GPC Measurement Conditions]

Measuring apparatus: “HLC-8220 GPC” manufactured by Tosoh Corporation

Column: “Shodex KF802” (8.0 mm φ×300 mm) manufactured by Showa Denko K.K.

+“Shodex KF802” (8.0 mm φ×300 mm) manufactured by Showa Denko K.K.
+“Shodex KF803” (8.0 mm φ×300 mm) manufactured by Showa Denko K.K.
+“Shodex KF804” (8.0 mm φ×300 mm) manufactured by Showa Denko K.K.

Column temperature: 40° C.

Detector: RI (differential refractometer)

Data processing: “GPC-8020 model II version 4.30” manufactured by Tosoh Corporation

Developing solvent: tetrahydrofuran

Flow rate: 1.0 ml/min

Sample: prepared by filtering a 0.5 mass % tetrahydrofuran solution in terms of resin solid with a microfilter.

Injection amount: 0.1 ml

Standard sample: monodisperse polystyrene described below.

### (Standard Sample: Monodisperse Polystyrene)

“A-500” manufactured by Tosoh Corporation

“A-2500” manufactured by Tosoh Corporation

“A-5000” manufactured by Tosoh Corporation

“F-1” manufactured by Tosoh Corporation

“F-2” manufactured by Tosoh Corporation

“F-4” manufactured by Tosoh Corporation

“F-10” manufactured by Tosoh Corporation

“F-20” manufactured by Tosoh Corporation

Examples of the poor solvent (S1) used for purifying the aromatic compound (A) include water; monoalcohols such as methanol, ethanol, propanol, ethoxyethanol, and the like; aliphatic hydrocarbons such as n-hexane, n-heptane, n-octane, cyclohexane, and the like; and aromatic hydrocarbons such as toluene, xylene, and the like. These solvents may be used alone or in combination of two or more. Among these, water, methanol, and ethoxyethanol are preferred because of excellent solubility of the acid catalyst.

On the other hand, examples of the solvent (S2) include monoalcohols such as methanol, ethanol, propanol, and the like; polyols such as ethylene glycol, 1,2-propanediol, 1,3-propanediol, 1,4-butanediol, 1,5-pentanediol, 1,6-hexanediol, 1,7-heptanediol, 1,8-octanediol, 1,9-nonanediol, trimethylene glycol, diethylene glycol, polyethylene glycol, glycerin, and the like; glycol ethers such as 2-ethoxyethanol, ethylene glycol monomethyl ether, ethylene glycol monoethyl ether, ethylene glycol monopropyl ether, ethylene glycol monobutyl ether, ethylene glycol monopentyl ether, ethylene glycol dimethyl ether, ethylene glycol ethyl methyl ether, ethylene glycol monophenyl ether, and the like; cyclic ethers such as 1,3-dioxaene, 1,4-dioxane, and the like; glycol esters such as ethylene glycol acetate and the like; and ketones such as acetone, methyl ethyl ketone, methyl isobutyl ketone, and the like. These solvents may be used alone or in combination of two or more. Among these, when water or monoalcohol is used as the poor solvent (S1), acetone is preferably used as the solvent (S2).

The novolac phenol resin (C) which is a precursor of the modified novolac phenol resin of the present invention can be produced by condensing the aromatic compound (A) with the aldehyde compound (B).

The aldehyde compound (B) used may be any aldehyde compound as long as it can form a novolac phenol resin by condensation reaction with the aromatic compound (A). Examples thereof include formaldehyde, para-formaldehyde, 1,3,5-trioxane, acetaldehyde, propionaldehyde, tetraoxymethylene, polyoxymethylene, chloral, hexamethylenetetramine, furfural, glyoxal, n-butylaldehyde, caproaldehyde, allyaldehyde, crotonaldehyde, acrolein, and the like. These may be used alone or in combination of two or more. Among these, formaldehyde is preferably used because of excellent reactivity. The formaldehyde may be used either as formalin in an aqueous solution state or as para-formaldehyde in a solid state. When formaldehyde is used in combination with another aldehyde compound, the other aldehyde compound is preferably used at a ratio of 0.05 to 1 mole per mole of formaldehyde.

The reaction molar ratio [(A)/(B)] of the aromatic compound (A) to the aldehyde compound (B) is preferably within a range of 1/0.5 to 1/1.2 and more preferably within a range of 1/0.6 to 1/0.9 because excessive increase in molecular weight (gelling) can be suppressed and the modified novolac phenol resin having a molecular weight appropriate for a resist material can be produced.

Examples of an acid catalyst used for reaction between the aromatic compound (A) and the aldehyde compound (B) include acetic acid, oxalic acid, sulfuric acid, hydrochloric acid, phenolsulfonic acid, para-toluenesulfonic acid, zinc acetate, manganese acetate, and the like. These acid catalysts may be used alone or in combination of two or more. Among these, sulfuric acid and para-toluenesulfonic acid are preferred because of excellent catalytic activity.

If required, the reaction between the aromatic compound (A) and the aldehyde compound (B) may be performed in an organic solvent. Examples of the solvent used include monoalcohols such as methanol, ethanol, propanol, and the like; polyols such as ethylene glycol, 1,2-propanediol, 1,3-propanediol, 1,4-butanediol, 1,5-pentanediol, 1,6-hexanediol, 1,7-heptanediol, 1,8-octanediol, 1,9-nonanediol, trimethylene glycol, diethylene glycol, polyethylene glycol, glycerin, and the like; glycol ethers such as 2-ethoxyethanol, ethylene glycol monomethyl ether, ethylene glycol monoethyl ether, ethylene glycol monopropyl ether, ethylene glycol monobutyl ether, ethylene glycol monopentyl ether, ethylene glycol dimethyl ether, ethylene glycol ethyl methyl ether, ethylene glycol monophenyl ether, and the like; cyclic ethers such as 1,3-dioxaene, 1,4-dioxane, tetrahydrofuran, and the like; glycol esters such as ethylene glycol acetate and the like; and ketones such as acetone, methyl ethyl ketone, methyl isobutyl ketone, and the like. These solvents may be used alone or as a mixed solvent of two or more. Among these, 2-ethoxyethanol is preferred because of excellent solubility of the resultant aromatic compound (A).

The reaction between the aromatic compound (A) and the aldehyde compound (B) is performed, for example, within a temperature range of 60° C. to 140° C. over a time of 0.5 to 100 hours.

The novolac phenol resin (C) can be produced by adding water to the reaction product and performing a re-precipitation operation after the completion of reaction. The weight-average molecular weight (Mw) of the resultant novolac phenol resin (C) is preferably within a range of 2,000 to 35,000 and within a range of 2,000 to 25,000 because the modified novolac phenol resin as a final object has excellent heat resistance and developability and is suitable for a resist material.

The polydispersity (Mw/Mn) of the resultant novolac phenol resin (C) is preferably within a range of 1.3 to 2.5 because the modified novolac phenol resin as a final object has excellent heat resistance and developability and is suitable for a resist material.

In addition, in the present invention, the weight-average molecular weight (Mw) and the polydispersity (Mw/Mn) are values measured by GPC under conditions described below.

### [GPC Measurement Conditions]

Measuring apparatus: “HLC-8220 GPC” manufactured by Tosoh Corporation

Column: “Shodex KF802” (8.0 mm φ×300 mm) manufactured by Showa Denko K.K.+“Shodex KF802” (8.0 mm φ×300 mm) manufactured by Showa Denko K.K.

+“Shodex KF803” (8.0 mm φ×300 mm) manufactured by Showa Denko K.K.+“Shodex KF804” (8.0 mm φ×300 mm) manufactured by Showa Denko K.K.

Column temperature: 40° C.

Detector: RI (differential refractometer)

Data processing: “GPC-8020 model II version 4.30” manufactured by Tosoh Corporation

Developing solvent: tetrahydrofuran

Flow rate: 1.0 mL/min

Sample: prepared by filtering a 0.5 mass % tetrahydrofuran solution in terms of resin solid with a microfilter (100 μl).

Standard sample: monodisperse polystyrene described below.

### (Standard Sample: Monodisperse Polystyrene)

“A-500” manufactured by Tosoh Corporation

“A-2500” manufactured by Tosoh Corporation

“A-5000” manufactured by Tosoh Corporation

“F-1” manufactured by Tosoh Corporation

“F-2” manufactured by Tosoh Corporation

“F-4” manufactured by Tosoh Corporation

“F-10” manufactured by Tosoh Corporation

“F-20” manufactured by Tosoh Corporation

The modified novolac phenol resin of the present invention has a molecular structure in which hydrogen atoms of phenolic hydroxyl groups possessed by the novolac phenol resin (C) are partially or entirely substituted by acid dissociable groups. Specific examples of the acid dissociable groups include a tertiary alkyl group, an alkoxyalkyl group, an acyl group, an alkoxycarbonyl group, a heteroatom-containing cyclic hydrocarbon group, a trialkylsilyl group, and the like. All acid dissociable groups in the resin may have the same structure or combination of a plurality of acid dissociable groups may be used.

Examples of the tertiary alkyl groups among the acid dissociable group include a tert-butyl group, a tert-pentyl group, and the like. Examples of the alkoxyalkyl group include a methoxyethyl group, an ethoxyethyl group, a propoxyethyl group, a butoxyethyl group, a cyclohexyloxyethyl group, a phenoxyethyl group, and the like. Examples of the acyl group include an acetyl group, an ethanoyl group, a propanoyl group, a butanoyl group, a cyclohexanecarbonyl group, a benzoyl group, and the like. Examples of the alkoxycarbonyl group include a methoxycarbonyl group, an ethoxycarbonyl group, a propoxycarbonyl group, a butoxycarbonyl group, a cyclohexyloxycarbonyl group, a phenoxycarbonyl group, and the like. Examples of the heteroatom-containing cyclic hydrocarbon group include a tetrahydrophenyl group, a tetrahydropyranyl group, and the like. Examples of the trialkylsilyl group include trimethylsilyl group, a triethylsilyl group, a tert-butyldimethylsilyl group, and the like.

Among these, any one of the alkoxyalkyl group, the alkoxycarbonyl group, and the heteroatom-containing cyclic hydrocarbon group is preferred because cleavage easily proceeds under the acid catalyst condition, and the modified novolac phenol resin having excellent photosensitivity, resolution, and alkali-developability can be produced, and any one of an ethoxyethyl group, a butoxycarbonyl group, and a tetrahydropyranyl group is preferred.

A presence ratio [(α)/(β)] of phenolic hydroxyl group (α) to acid dissociable group (β) in the modified novolac phenol resin is preferably within a range of 95/5 to 10/90 and more preferably within a range of 85/15 to 20/80 because of a large change in solubility in a developer before and after exposure and good contrast performance.

The presence ratio [(α)/(β)] of phenolic hydroxyl group (α) to acid dissociable group (β) in the modified novolac phenol resin is a value calculated from a ratio of a peak at 145 to 160 ppm due to carbon atoms on benzene rings to which phenolic hydroxyl groups are bonded to a peak at 95 to 105 ppm due to carbon atoms bonded to oxygen atoms of phenolic hydroxyl groups in the acid dissociable groups in 13C-NMR measurement performed under conditions described below.

Apparatus: “JNM-LA300” manufactured by JEOL Ltd.

Solvent: DMSO-d₆

A method for partially or entirely substituting hydrogen atoms of the phenolic hydroxyl groups possessed by the novolac phenol resin (C) by the acid dissociable groups is, for example, a method of reacting the novolac phenol resin (C) with a compound (hereinafter abbreviated as an “acid dissociable group-introducing agent”) represented by any one of structural formulae (3-1) to (3-8) below

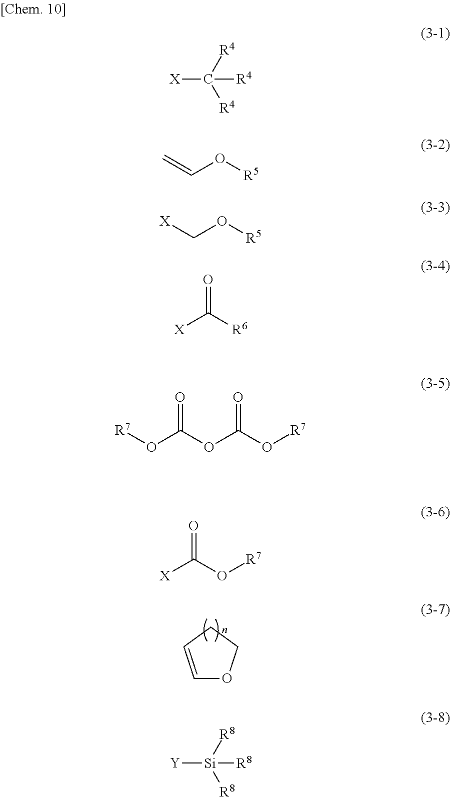

(in the formulae, X represents a halogen atom, Y represents a halogen atom or a trifluoromethanesulfonyl group, R⁴ to R⁸ each independently represent an alkyl group having 1 to 6 carbon atoms or a phenyl group, and n is 1 or 2).

Among the acid dissociable group-introducing agents, a compound represented by the structural formula (3-2), (3-5), or (3-7) is preferred because cleavage easily proceeds under the acid catalyst condition, and the resin having excellent photosensitivity, resolution, and alkali-developability can be produced, and ethyl vinyl ether, di-tert-butyl dicarbonate, and dihydropyran are particularly preferred.

The reaction of the novolac phenol resin (C) with the acid dissociable group-introducing agent represented by any one of the structural formulae (3-1) to (3-8) varies with the compound used as the acid dissociable group-introducing agent. For example, when a compound represented by any one of the structural formulae (3-1), (3-3), (3-4), (3-5), (3-6), and (3-8) is used as the acid dissociable group-introducing agent, a method of reaction under a basic catalyst condition, for example, pyridine, triethylamine, or the like, can be used. When a compound represented by the structural formula (3-2) or (3-7) is used as the protecting group-introducing agent, a method of reaction under an acid catalyst condition, for example, hydrochloric acid or the like, can be used.

The reaction ratio of the novolac phenol resin (C) to the acid dissociable group-introducing agent represented by any one of the structural formulae (3-1) to (3-8) varies with which compound is used as the acid dissociable group-introducing agent. For example, the acid dissociable group-introducing agent is preferably reacted at a ratio of 0.1 to 0.75 moles, more preferably at a ratio of 0.15 to 0.5 moles to 1 mole of a total of phenolic hydroxyl groups of the novolac phenol resin (C).

The reaction of the novolac phenol resin (C) with the acid dissociable group-introducing agent may be performed in an organic solvent. Examples of the organic solvent include 1,3-dioxolane and the like. The organic solvents may be used alone or as a mixed solvent of two or more.

The intended modified novolac phenol resin can be produced by pouring the reaction mixture into ion exchange water after the completion of reaction and then drying the resultant precipitate under reduced pressure.

A photosensitive composition of the present invention contains the modified novolac phenol resin and a photoacid generator as essential components.

Examples of the photoacid generator used in the present invention include organic halogen compounds, sulfonic acid esters, onium salts, diazonium salts, disulfone compounds, and the like. These may be used alone or in combination of two or more. Specific examples thereof include haloalkyl group-containing s-triazine derivatives such as tris(trichloromethyl)-s-triazine, tris(tribromomethyl)-s-triazine, tris(dibromomethyl)-s-triazine, 2,4-bis(tribromomethyl)-6-p-methoxyphenyl-s-triazine, and the like;

halogen-substituted paraffin-based hydrocarbon compounds such as 1,2,3,4-tetrabromobutane, 1,1,2,2-tetrabromoethane, carbon tetrabromide, iodoform, and the like; halogen-substituted cycloparaffin-based hydrocarbon compounds such as hexabromocyclohexane, hexachlorocyclohexane, hexabromocyclododecane, and the like;

haloalkyl group-containing benzene derivatives such as bis(trichloromethyl)benzene, bis(tribromomethyl)benzene, and the like; haloalkyl group-containing sulfone compounds such as tribromomethylphenyl sulfone, trichloromethylphenyl sulfone, and the like; halogen-containing sulfolane compounds such as 2,3-dibromosulfolane and the like; haloalkyl group-containing isocyanurate compounds such as tris(2,3-dibromopropyl) isocyanurate and the like;

sulfonium salts such as triphenylsulfonium chloride, diphenyl-4-methylphenylsulfonium trifluoromethane sulfonate, triphenylsulfonium methane sulfonate, triphenylsulfonium trifluoromethane sulfonate, triphenylsulfonium p-toluenesulfonate, triphenylsulfonium tetrafluoroborate, triphenylsulfonium hexafluoroarsenate, triphenylsulfonium hexafluorophosphonate, and the like;

iodonium salts such as diphenyliodonium trifluoromethane sulfonate, diphenyliodonium p-toluenesulfonate, diphenyliodonium tetrafluoroborate, diphenyliodonium hexafluoroarsenate, diphenyliodonium hexafluorophosphonate, and the like;

sulfonic acid ester compounds such as methyl p-toluenesulfonate, ethyl p-toluenesulfonate, butyl p-toluenesulfonate, phenyl p-toluenesulfonate, 1,2,3-tris(p-toluenesulfonyloxy)benzene, benzoin p-toluenesulfonate, methyl methanesulfonate, ethyl methanesulfonate, butyl methanesulfonate, 1,2,3-tris(methanesulfonyloxy)benzene, phenyl methanesulfonate, benzoin methanesulfonate, methyl trifluoromethanesulfonate, ethyl trifluoromethanesulfonate, butyl trifluoromethanesulfonate, 1,2,3-tris(trifluoromethanesulfonyloxy)benzene, phenyl trifluoromethanesulfonate, benzoin trifluoromethanesulfonate, and the like; disulfone compounds such as diphenyl disulfone and the like;

sulfone diazide compounds such as bis(phenylsulfonyl)diazomethane, bis(2,4-dimethylphenylsulfonyl)diazomethane, bis(cyclohexylsulfonyl)diazomethane, cyclohexylsulfonyl-(2-methoxyphenylsulfonyl)diazomethane, cyclohexylsulfonyl-(3-methoxyphenylsulfonyl)diazomethane, cyclohexylsulfonyl-(4-methoxyphenylsulfonyl)diazomethane, cyclopentylsulfonyl-(2-methoxyphenylsulfonyl)diazomethane, cyclopentylsulfonyl-(3-methoxyphenylsulfonyl)diazomethane, cyclopentylsulfonyl-(4-methoxyphenylsulfonyl)diazomethane, cyclohexylsulfonyl-(2-fluorophenylsulfonyl)diazomethane, cyclohexylsulfonyl-(3-fluorophenylsulfonyl)diazomethane, cyclohexylsulfonyl-(4-fluorophenylsulfonyl)diazomethane, cyclopentylsulfonyl-(2-fluorophenylsulfonyl)diazomethane, cyclopentylsulfonyl-(3-fluorophenylsulfonyl)diazomethane, cyclopentylsulfonyl-(4-fluorophenylsulfonyl)diazomethane, cyclohexylsulfonyl-(2-chlorophenylsulfonyl)diazomethane, cyclohexylsulfonyl-(3-chlorophenylsulfonyl)diazomethane, cyclohexylsulfonyl-(4-chlorophenylsulfonyl)diazomethane, cyclopentylsulfonyl-(2-chlorophenylsulfonyl)diazomethane, cyclopentylsulfonyl-(3-chlorophenylsulfonyl)diazomethane, cyclopentylsulfonyl-(4-chlorophenylsulfonyl)diazomethane, cyclohexylsulfonyl-(2-trifluoromethylphenylsulfonyl)diazomethane, cyclohexylsulfonyl-(3-trifluoromethylphenylsulfonyl)diazomethane, cyclohexylsulfonyl-(4-trifluoromethylphenylsulfonyl)diazomethane, cyclopentylsulfonyl-(2-trifluoromethylphenylsulfonyl)diazomethane, cyclopentylsulfonyl-(3-trifluoromethylphenylsulfonyl)diazomethane, cyclopentylsulfonyl-(4-trifluoromethylphenylsulfonyl)diazomethane, cyclohexylsulfonyl-(2-trifluoromethoxyphenylsulfonyl)diazomethane, cyclohexylsulfonyl-(3-trifluoromethoxyphenylsulfonyl)diazomethane, cyclohexylsulfonyl-(4-trifluoromethoxyphenylsulfonyl)diazomethane, cyclopentylsulfonyl-(2-trifluoromethoxyphenylsulfonyl) diazomethane, cyclopentylsulfonyl-(3-trifluoromethoxyphenylsulfonyl)diazomethane, cyclopentylsulfonyl-(4-trifluoromethoxyphenylsulfonyl)diazomethane, cyclohexylsulfonyl-(2,4,6-trimethylphenylsulfonyl)diazomethane, cyclohexylsulfonyl-(2,3,4-trimethylphenylsulfonyl)diazomethane, cyclohexylsulfonyl-(2,4,6-triethylphenylsulfonyl)diazomethane, cyclohexylsulfonyl-(2,3,4-triethylphenylsulfonyl)diazomethane, cyclopentylsulfonyl-(2,4,6-trimethylphenylsulfonyl)diazomethane, cyclopentylsulfonyl-(2,3,4-trimethylphenylsulfonyl)diazomethane, cyclopentylsulfonyl-(2,4,6-triethylphenylsulfonyl)diazomethane, cyclopentylsulfonyl-(2,3,4-triethylphenylsulfonyl)diazomethane, phenylsulfonyl-(2-methoxyphenylsulfonyl)diazomethane, phenylsulfonyl-(3-methoxyphenylsulfonyl)diazomethane, phenylsulfonyl-(4-methoxyphenylsulfonyl)diazomethane, bis(2-methoxyphenylsulfonyl)diazomethane, bis(3-methoxyphenylsulfonyl)diazomethane, bis(4-methoxyphenylsulfonyl)diazomethane, phenylsulfonyl-(2,4,6-trimethylphenylsulfonyl)diazomethane, phenylsulfonyl-(2,3,4-trimethylphenylsulfonyl)diazomethane, phenylsulfonyl-(2,4,6-triethylphenylsulfonyl)diazomethane, phenylsulfonyl-(2,3,4-triethylphenylsulfonyl)diazomethane, 2,4-dimethylphenylsulfonyl-(2,4,6-trimethylphenylsulfonyl) diazomethane, 2,4-dimethylphenylsulfonyl-(2,3,4-trimethylphenylsulfonyl)diazomethane, phenylsulfonyl-(2-fluorophenylsulfonyl)diazomethane, phenylsulfonyl-(3-fluorophenylsulfonyl)diazomethane, phenylsulfonyl-(4-fluorophenylsulfonyl)diazomethane, and the like;

o-nitrobenzyl ester compounds such as o-nitrobenzyl-p-toluenesulfonate, and the like; and sulfone hydrazide compounds such as N,N′-di(phenylsulfonyl) hydrazide and the like.

The amount of the photoacid generator added is preferably within a range of 0.1 to 20 parts by mass relative to 100 parts by mass of the modified novolac phenol resin of the present invention because the photosensitive composition having high photosensitivity can be produced.

The photosensitive composition of the present invention may contain an organic base compound for neutralizing the acid produced from the photoacid generator during exposure. The addition of the organic base compound has the effect of preventing dimensional variation in a resist pattern due to movement of the acid generated from the photoacid generator. The organic base compound used is, for example, an organic amine compound selected from nitrogen-containing compounds. Examples thereof include pyrimidine compounds such as pyrimidine, 2-aminopyrimidine, 4-aminopyrimidine, 5-aminopyrimidine, 2,4-diaminopyrimidine, 2,5-diaminopyrimidine, 4,5-diaminopyrimidine, 4,6-diaminopyrimidine, 2,4,5-triaminopyrimidine, 2,4,6-triaminopyrimidine, 4,5,6-triaminopyrimidine, 2,4,5,6-tetraaminopyrimidine, 2-hyroxypyrimidine, 4-hyroxypyrimidine, 5-hyroxypyrimidine, 2,4-dihyroxypyrimidine, 2,5-dihyroxypyrimidine, 4,5-dihyroxypyrimidine, 4,6-dihyroxypyrimidine, 2,4,5-trihyroxypyrimidine, 2,4,6-trihyroxypyrimidine, 4,5,6-trihyroxypyrimidine, 2,4,5,6-tetrahyroxypyrimidine, 2-amino-4-hyroxypyrimidine, 2-amino-5-hyroxypyrimidine, 2-amino-4,5-dihyroxypyrimidine, 2-amino-4,6-dihyroxypyrimidine, 4-amino-2,5-dihyroxypyrimidine, 4-amino-2,6-dihyroxypyrimidine, 2-amino-4-methylpyrimidine, 2-amino-5-methylpyrimidine, 2-amino-4,5-dimethylpyrimidine, 2-amino-4,6-dimethylpyrimidine, 4-amino-2,5-dimethylpyrimidine, 4-amino-2,6-dimethylpyrimidine, 2-amino-4-methoxypyrimidine, 2-amino-5-methoxypyrimidine, 2-amino-4,5-dimethoxypyrimidine, 2-amino-4,6-dimethoxypyrimidine, 4-amino-2,5-dimethoxypyrimidine, 4-amino-2,6-dimethoxypyrimidine, 2-hydroxy-4-methylpyrimidine, 2-hydroxy-5-methylpyrimidine, 2-hydroxy-4,5-dimethylpyrimidine, 2-hydroxy-4,6-dimethylpyrimidine, 4-hydroxy-2,5-dimethylpyrimidine, 4-hydroxy-2,6-dimethylpyrimidine, 2-hydroxy-4-methoxypyrimidine, 2-hydroxy-4-methoxypyrimidine, 2-hydroxy-5-methoxypyrimidine, 2-hydroxy-4,5-dimethoxypyrimidine, 2-hydroxy-4,6-dimethoxypyrimidine, 4-hydroxy-2,5-dimethoxypyrimidine, 4-hydroxy-2,6-dimethoxypyrimidine, and the like;

pyridine compounds such as pyridine, 4-dimethylaminopyridine, 2,6-dimethylpyridine, and the like;

amine compounds substituted by a hydroxyalkyl group having 1 to 4 carbon atoms, such as diethanolamine, triethanolamine, triisopropanolamine, tris(hydroxymethyl)aminomethane, bis(2-hydroxyethyl)iminotris(hydroxymethyl) methane, and the like; and

aminophenol compounds such as 2-aminophenol, 3-aminophenol, 4-aminophenol, and the like. These may be used alone or in combination of two or more. Among these, the pyrimidine compounds, the pyridine compounds, or the hydroxyl group-containing amine compounds are preferred because of the excellent dimensional stability of a resist pattern after exposure, and the hydroxyl group-containing amine compounds are particularly preferred.

When the organic base compound is added, the adding amount is preferably within a range of 0.1 to 100 mol % and more preferably within a range of 1 to 50 mol % relative to the content of the photoacid generator.

The photosensitive composition of the present invention may contain another alkali-soluble resin in addition to the modified novolac phenol resin of the present invention. Any desired alkali-soluble resin can be used as the other alkali-soluble resin as long as it is soluble in an alkali developer, or like the modified novolac phenol resin of the present invention, it is dissolved in an alkali developer by using in combination with an additive such as the photoacid generator or the like.

Examples of the other alkali-soluble resin used include a phenolic hydroxyl group-containing resin other than the modified hydroxynaphthalene novolac phenol resin, a homopolymer or copolymer of a hydroxyl group-containing styrene compound such as p-hydroxystyrene, p-(1,1,1,3,3,3-hexafluoro-2-hydroxypropyl)styrene, or the like, a resin having a hydroxyl group modified with an acid dissociable group, such as a carbonyl group, a benzyloxycarbonyl group, or the like, as in the modified hydroxynaphthalene novolac phenol resin of the present invention, a homopolymer or copolymer of (meth)acrylic acid, an alternating copolymer of an alicyclic polymerizable monomer such as a norbornene compound, a tetracyclododecene compound, or the like with maleic anhydride or maleimide, and the like.

Examples of the phenolic hydroxyl group-containing resin other than the modified novolac phenol resin include phenol resins such as phenol novolac resins, cresol novolac resins, naphthol novolac resins, co-condensation novolac resins using various phenolic compounds, aromatic hydrocarbon formaldehyde resin-modified phenol resins, dicyclopentadiene phenol-adduct resins, phenol aralkyl resins (Xylok resins), naphthol aralkyl resins, trimethylol methane resins, tetraphenylol ethane resins, biphenyl-modified phenol resins (polyhydric phenol compound in which phenol nuclei are connected through a bismethylene group), biphenyl-modified naphthol resins (polyhydric naphthol compound in which phenol nuclei are connected through a bismethylene group), aminotriazine-modified phenol resins (polyhydric phenol compound in which phenol nuclei are connected through melamine, benzoguanamine, or the like), alkoxy group-containing aromatic ring-modified novolac resins (polyhydric phenol compound in which a phenol nucleus and an alkoxy group-containing aromatic ring are connected through formaldehyde), and the like.

Among the other phenolic hydroxyl group-containing phenol resins, cresol novolac resins or co-condensation novolac resins of cresol with other phenol compounds are preferred because the photosensitive resin composition having high sensitivity and excellent heat resistance can be produced. Specifically, the cresol novolac resins or co-condensation novolac resins of cresol with other phenol compounds are novolac resins produced by using at least one cresol selected from the group consisting of o-cresol, m-cresol, and p-cresol and an aldehyde compound as essential raw materials, and appropriately using another phenolic compound in combination with the cresol.

Examples of the other phenolic compound include phenol; xylenols such as 2,3-xylenol, 2,4-xylenol, 2,5-xylenol, 2,6-xylenol, 3,4-xylenol, 3,5-xylenol, and the like; ethyl phenols such as o-ethyl phenol, m-ethyl phenol, p-ethyl phenol, and the like; isopropyl phenol; butylphenol such as butylphenol, p-tert-butyl phenol, and the like; alkylphenols such as p-pentylphenol, o-octylphenol, p-nonylphenol, p-cumylphenol, and the like; halogenated phenols such as fluorophenol, chlorophenol, bromophenol, iodophenol, and the like; mono-substituted phenols such as p-phenylphenol, aminophenol, nitrophenol, dinitrophenol, trinitrophenol, and the like; condensed polycyclic phenols such as 1-naphthol, 2-naphthol, and the like; and polyhydric phenols such as resorcin, alkylresorcin, pyrogallol, catechol, alkylcatechol, hydroquinone, alkylhydroquinone, fluoroglycine, bisphenol A, bisphenol F, bisphenol S, dihydroxynaphthalene, and the like. These other phenolic compounds may be used alone or in combination of two or more. When the other phenolic compound is added, the use amount is preferably within a range of 0.05 to 1 mole relative to a total of 1 mole of the cresol raw material.

Examples of the aldehyde compound include formaldehyde, para-formaldehyde, trioxane, acetaldehyde, propionaldehyde, polyoxymethylene, chloral, hexamethylenetetramine, furfural, glyoxal, n-butylaldehyde, caproaldehyde, allyaldehyde, benzaldehyde, crotonaldehyde, acrolein, tetraoxymethylene, phenylacetaldehyde, o-tolualdehyde, salicylic aldehyde, and the like. These may be used alone or in combination of two or more. Among these, formaldehyde is preferably used because of excellent reactivity, and formaldehyde may be used in combination with another aldehyde compound. When formaldehyde is used in combination with another aldehyde compound, the amount of the other aldehyde compound used is preferably within a range of 0.05 to 1 mole per mole of formaldehyde.

With respect to the reaction ratio between the phenolic compound to the aldehyde compound for producing the novolac resin, the amount of the aldehyde compound is preferably within a range of 0.3 to 1.6 moles and more preferably within a range of 0.5 to 1.3 relative to 1 mole of the phenolic compound because the photosensitive resin composition having excellent sensitivity and heat resistance can be produced.

A method for reacting the phenolic compound with the aldehyde compound includes, for example, performing reaction in the presence of an acid catalyst under a temperature condition of 60° C. to 140° C., and then removing water and residual monomers under a reduced pressure condition. Examples of the acid catalyst used include oxalic acid, sulfuric acid, hydrochloric acid, phenolsulfonic acid, para-toluenesulfonic acid, zinc acetate, manganese acetate, and the like. These acid catalysts may be used alone or in combination of two or more. Among these, oxalic acid is preferred because of excellent catalytic activity.

Among the cresol novolac resins or co-condensation novolac resins of cresol with other phenolic compounds detailed above, a cresol novolac resin using meta-cresol alone or a cresol novolac resin using combination of meta-cresol and para-cresol is preferred. In the latter, the reaction molar ratio [meta-cresol/para-cresol] of meta-cresol to para-cresol is preferably within a range of 10/0 to 2/8 and more preferably within a range of 7/3 to 2/8 because the photosensitive resin composition having excellent balance between sensitivity and heat resistance can be produced.

When the other alkali-soluble resin is used, the mixing ratio between the modified novolac phenol resin of the present invention and the other alkali-soluble resin can be arbitrarily adjusted according to desired application. In particular, the modified novolac phenol resin of the present invention is preferably used in an amount of 60% by mass or more and more preferably 80% by mass or more relative to the total of the modified novolac phenol resin of the present invention and the other alkali-soluble resin because the effect of exhibiting excellent heat resistance and developability of the present invention can be sufficiently exhibited.

The photosensitive composition of the present invention may further contain a photosensitizer used for general resist materials. Examples of the photosensitizer used include a compound having a quinone diazide group. Examples of the compound having a quinone diazide group include complete ester compounds, partial ester compounds, amidated products, and partially amidated products of aromatic (poly)hydroxy compounds and sulfonic acid having a quinone diazide group, such as naphthoquinone-1,2-diazido-5-sulfonic acid, naphthoquinone-1,2-diazido-4-sulfonic acid, ortho-anthraquinone diazidosulfonic acid, or the like.

Examples of the aromatic (poly)hydroxy compounds used include polyhydroxybenzophenone compounds such as 2,3,4-trihydroxybnezophenone, 2,4,4′-trihydroxybenzophenone, 2,4,6-trihydroxybenzophenone, 2,3,6-trihydroxybenzophenone, 2,3,4-trihydroxy-2′-methylbenzophenone, 2,3,4,4′-tetrahydroxybenzophenone, 2,2′,4,4′-tetrahydroxybenzophenone, 2,3′,4,4′,6-pentahydroxybenzophenone, 2,2′,3,4,4′-pentahydroxybenzophenone, 2,2′,3,4,5′-pentahydroxybenzophenone, 2,3′,4,4′,5′,6-hexahydroxybenzophenone, 2,3,3′,4,4′,5″-hexahydroxybenzophenone, and the like;

bis[(poly)hydroxyphenyl]alkane compounds such as bis(2,4-dihydroxyphenyl)methane, bis(2,3,4-trihydroxyphenyl)methane, 2-(4-hydroxyphenyl)-2-(4′-hydroxyphenyl)propane, 2-(2,4-dihydroxyphenyl)-2-(2′,4′-dihydroxyphenyl)propane, 2-(2,3,4-trihydroxyphenyl)-2-(2′,3′,4′-trihydroxyphenyl)propane, 4,4′-{1-[4-[2-(4-hydroxyphenyl)-2-propyl]phenyl]ethylidene}bisphenol, 3,3′-dimethyl-{1-[4-[2-(3-methyl-4-hydroxyphenyl)-2-propyl]phenyl]ethylidene}bisphenol, and the like;

tris(hydroxyphenyl)methane compounds and methyl-substituted compounds thereof, such as tris(4-hydroxyphenyl)methane, bis(4-hydroxy-3,5-dimethylphenyl)-4-hydroxyphenylmethane, bis(4-hydroxy-2,5-dimethylphenyl)-4-hydroxyphenylmethane, bis(4-hydroxy-3,5-dimethylphenyl)-2-hydroxyphenylmethane, bis(4-hydroxy-2,5-dimethylphenyl)-2-hydroxyphenylmethane, bis(4-hydroxy-2,5-dimethylphenyl)-3,4-dihydroxyphenylmethane, bis(4-hydroxy-3,5-dimethylphenyl)-3,4-diydroxyphenylmethane, and the like; and

bis(cyclohexylhydroxyphenyl)(hydroxyphenyl)methane compounds and methyl-substituted compounds thereof, such as bis(3-cyclohexyl-4-hydroxyphenyl)-3-hydroxyphenylmethane, bis(3-cyclohexyl-4-hydroxyphenyl)-2-hydroxyphenylmethane, bis(3-cyclohexyl-4-hydroxyphenyl)-4-hydroxyphenylmethane, bis(5-cyclohexyl-4-hydroxy-2-methylphenyl)-2-hydroxyphenylmethane, bis(5-cyclohexyl-4-hydroxy-2-methylphenyl)-3-hydroxyphenylmethane, bis(5-cyclohexyl-4-hydroxy-2-methylphenyl)-4-hydroxyphenylmethane, bis(3-cyclohexyl-2-hydroxyphenyl)-3-hydroxyphenylmethane, bis(5-cyclohexyl-4-hydroxy-3-methylphenyl)-4-hydroxyphenylmethane, bis(5-cyclohexyl-4-hydroxy-3-methylphenyl)-3-hydroxyphenylmethane, bis(5-cyclohexyl-4-hydroxy-3-methylphenyl)-2-hydroxyphenylmethane, bis(3-cyclohexyl-2-hydroxyphenyl)-4-hydroxyphenylmethane, bis(3-cyclohexyl-2-hydroxyphenyl)-2-hydroxyphenylmethane, bis(5-cyclohexyl-2-hydroxy-4-methylphenyl)-2-hydroxyphenylmethane, bis(5-cyclohexyl-2-hydroxy-4-methylphenyl)-4-hydroxyphenylmethane, and the like. These photosensitizers may be used alone or in combination of two or more.

When the photosensitizer is used, the mixing amount is preferably within a range of 5 to 30 parts by mass relative to 100 parts by mass of the resin solid content in the photosensitive composition of the present invention because the composition has excellent photosensitivity.

The photosensitive composition of the present invention may contain a surfactant for the purpose of improving film formability and pattern adhesion and decreasing development defects when used for resist application. Examples of the surfactant used include nonionic surfactants, such as polyoxyethylene alkyl ether compounds such as polyoxyethylene lauryl ether, polyoxyethylene stearyl ether, polyoxyethylene cetyl ether, polyoxyethylene oleyl ether, and the like; polyoxyethylene alkyl allyl ether compounds such as polyoxyethylene octylphenol ether, polyoxyethylene nonylphenol ether, and the like; polyoxyethylene-polyoxypropylene block copolymer; sorbitan fatty acid ester compounds such as sorbitan monolaurate, sorbitan monopalmitate, sorbitan monostearate, sorbitan monooleate, sorbitan trioleate, sorbitan tristearate, and the like; polyoxyethylene sorbitan fatty acid ester compounds such as polyoxyethylene sorbitan monolaurate, polyoxyethylene sorbitan monopalmitate, polyoxyethylene sorbitan monostearate, polyoxyethylene sorbitan trioleate, polyoxyethylene sorbitan tristearate, and the like; fluorine-based surfactants each having a fluorine atom in its molecular structure, such as a copolymer of a polymerizable monomer having a fluoroaliphatic group and [poly(oxyalkylene)](meth)acrylate, and the like; silicone-based surfactants each having a silicone structural moiety in its molecular structure, and the like. These may be used alone or in combination of two or more.

The mixing amount of the surfactant is preferably within a range of 0.001 to 2 parts by mass relative to 100 parts by mass of the resin solid content in the photosensitive composition of the present invention.

When the photosensitive composition of the present invention is used for photoresist application, a resist material can be produced by adding the modified novolac phenol resin, the photoacid generator, and, if required, various additives such as the organic base compound, another resin, a photosensitizer, a surfactant, a dye, a filler, a crosslinking-agent, a dissolution accelerator, and the like, and dissolving these materials in an organic solvent. The resist material may be used directly as a positive resist solution or may be applied in a film form and used as a positive resist film after solvent removal. In the use as the resist film, examples of a support film include synthetic resin films of polyethylene, polypropylene, polycarbonate, polyethylene terephthalate, and the like, and a single-layer film or multilayered film may be used. A surface of the support film may be subjected to corona treatment or coated with a release agent.

Examples of the organic solvent used in the resist material of the present invention include alkylene glycol monoalkyl ethers such as ethylene glycol monomethyl ether, ethylene glycol monoethyl ether, ethylene glycol monopropyl ether, ethylene glycol monobutyl ether, propylene glycol monomethyl ether, and the like; dialkylene glycol dialkyl ethers such as diethylene glycol dimethyl ether, diethylene glycol diethyl ether, diethylene glycol dipropyl ether, diethylene glycol dibutyl ether, and the like; alkylene glycol alkyl ether acetates such as ethylene glycol monomethyl ether acetate, ethylene glycol monoethyl ether acetate, propylene glycol monomethyl ether acetate, and the like; ketone compounds such as acetone, methyl ethyl ketone, cyclohexanone, methyl amyl ketone, and the like; cyclic ethers such as dioxane and the like; ester compounds such as methyl 2-hydroxypropionate, ethyl 2-hydroxypropionate, ethyl 2-hydroxy-2-methylpropionate, ethyl ethoxyacetate, ethyl oxyacetate, methyl 2-hydroxy-3-methylbutanoate, 3-methoxybutyl acetate, 3-methyl-3-methoxybutyl acetate, ethyl formate, ethyl acetate, butyl acetate, methyl acetoacetate, ethyl acetoacetate, and the like. These may be used alone or in combination of two or more.

The photosensitive composition of the present invention can be prepared by mixing the components described above using a stirrer or the like. When the photosensitive composition contains a filler and a pigment, the photosensitive composition can be prepared by dispersing or mixing by using a dispersing apparatus such as a dissolver, a homogenizer, a three-roll mill, or the like.

In a photolithography method using the resist material including the photosensitive composition of the present invention, for example, the resist material is applied to an object for silicon substrate photolithography and then pre-baked under a temperature condition of 60° C. to 150° C. An application method may be any one of methods such as spin coating, roll coating, flow coating, dip coating, spray coating, doctor blade coating, and the like. Next, when a resist pattern is formed, since the resist material of the present invention is a positive type, an intended resist pattern is exposed through a predetermined mask, and exposed portions are dissolved in an alkali developer to form a resist pattern.

Examples of an exposure light source include infrared light, visible light, ultraviolet light, far ultraviolet light, X-rays, electron beams, and the like. Examples of ultraviolet light include high-pressure mercury lamp g line (wavelength 436 nm), h line (wavelength 405 nm), and i line (wavelength 365 nm), KrF excimer laser (wavelength 248 nm), ArF excimer laser (wavelength 193 nm), F2 excimer laser (wavelength 157 nm), EUV laser (wavelength 13.5 nm), and the like.

Because the photosensitive composition of the present invention has high photosensitivity and alkali developability, the resist pattern can be formed with high resolution even by using any light source.

### Examples

The present invention is described in further detail below by giving specific examples. In addition, the number-average molecular weight (Mn), the weight-average molecular weight (Mw), and polydispersity (Mw/Mn) of a synthesized resin are values measured by GPC under conditions described below.

### [GPC Measurement Conditions]

Measuring apparatus: “HLC-8220 GPC” manufactured by Tosoh Corporation

Column: “Shodex KF802” (8.0 mm φ×300 mm) manufactured by Showa Denko K.K.+“Shodex KF802” (8.0 mm φ×300 mm) manufactured by Showa Denko K.K.

+“Shodex KF803” (8.0 mm φ×300 mm) manufactured by Showa Denko K.K.+“Shodex KF804” (8.0 mm φ×300 mm) manufactured by Showa Denko K.K.

Column temperature: 40° C.

Detector: RI (differential refractometer)

Data processing: “GPC-8020 model II version 4.30” manufactured by Tosoh Corporation

Developing solvent: tetrahydrofuran

Flow rate: 1.0 mL/min

Sample: prepared by filtering a 0.5 mass % tetrahydrofuran solution in terms of resin solid content with a microfilter.

Injection amount: 0.1 mL

Standard sample: monodisperse polystyrene described below.

### (Standard Sample: Monodisperse Polystyrene)

“A-500” manufactured by Tosoh Corporation

“A-2500” manufactured by Tosoh Corporation

“A-5000” manufactured by Tosoh Corporation

“F-1” manufactured by Tosoh Corporation

“F-2” manufactured by Tosoh Corporation

“F-4” manufactured by Tosoh Corporation

“F-10” manufactured by Tosoh Corporation

“F-20” manufactured by Tosoh Corporation

The presence ratio [(α)/(β)] of phenolic hydroxyl group (α) to acid dissociable group (β) in the modified novolac phenol resin was calculated from a ratio of a peak at 145 to 160 ppm due to carbon atoms on benzene rings to which phenolic hydroxyl groups are bonded to a peak at 95 to 105 ppm due to carbon atoms bonded to oxygen atoms of phenolic hydroxyl groups in the acid dissociable groups in 13C-NMR measurement performed under conditions described below.

Apparatus: “JNM-LA300” manufactured by JEOL Ltd.

Solvent: DMSO-d₆

### Production Example 1

### Production of Aromatic Compound (A1)

In a 100 ml two-neck flask provided with a condenser, 36.6 g (0.3 mol) of 2,5-xylenol and 12.2 g (0.1 mol) of 4-hydroxybenzaldehyde were charged and dissolved in 100 ml of 2-ethoxyethanol. Then, 10 ml of sulfuric acid was added to the resultant solution under cooling in an ice bath, and then the resultant mixture was heated in an oil bath of 100° C. for 2 hours and subjected to reaction by stirring. After the reaction, the resultant solution was re-precipitated with water to produce a crude product. The resultant crude product was re-dissolved in acetone and further re-precipitated with water, and the resultant product was filtered off and dried under vacuum to produce 28.2 g of light brown crystals of aromatic compound (A1) represented by structural formula below.

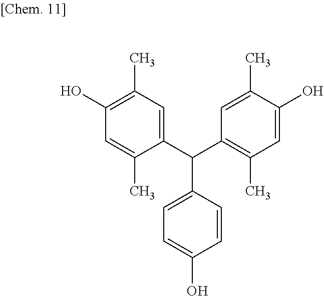 [SMILES: Cc1cc(C(c2ccc(O)cc2)c2cc(C)c(O)cc2C)c(C)cc1O]

### Production Example 2

### Production of Aromatic Compound (A2)

Excepting that 36.6 g (0.3 ml) of 2,6-xylenol and 12.2 g (0.1 mol) of 4-hydroxybenzaldehyde were used as raw materials, the same operation as in Synthesis Example 1 were performed to produce 28.5 g of orange crystals of aromatic compound (A2) represented by structural formula below.

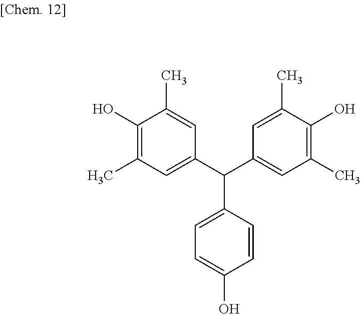 [SMILES: Cc1cc(C(c2ccc(O)cc2)c2cc(C)c(O)c(C)c2)cc(C)c1O]

### Production Example 3

### Production of Novolac Phenol Resin (C1)

In a 300 ml four-neck flask provided with a condenser, 17.4 g (50 mmol) of the aromatic compound (A1) produced in Production Example 1 and 1.6 g (50 mmol) of 92% para-formaldehyde were charged and dissolved in 50 ml of 2-ethoxyethanol and 50 ml of acetic acid. Then, 5 ml of sulfuric acid was added to the resultant solution under cooling in an ice bath, and then the resultant mixture was heated in an oil bath of 70° C. for 4 hours and subjected to reaction by stirring. After the reaction, the resultant solution was re-precipitated with water to produce a crude product. The resultant crude product was re-dissolved in acetone and further re-precipitated with water, and the resultant product was filtered off and dried under vacuum to produce 17.0 g of light brown powder of novolac phenol resin (C1). The novolac phenol resin (C1) had a number-average molecular weight (Mn) of 6,601, a weight-average molecular weight (Mw) of 14,940, and a polydispersity (Mw/Mn) of 2.263.

### Production Example 4

### Production of Novolac Phenol Resin (C1)

Excepting that 17.4 g (50 mmol) of the aromatic compound (A2) and 1.6 g (50 mmol) of 92% para-formaldehyde were used as raw materials, the same operations as in Production Example 3 were performed to produce 16.8 g of light brown powder of novolac phenol resin (C2). The novolac phenol resin (C2) had a number-average molecular weight (Mn) of 1,917, a weight-average molecular weight (Mw) of 2,763, and a polydispersity (Mw/Mn) of 1.441.

### Example 1

### Production of Modified Novolac Phenol Resin (1)

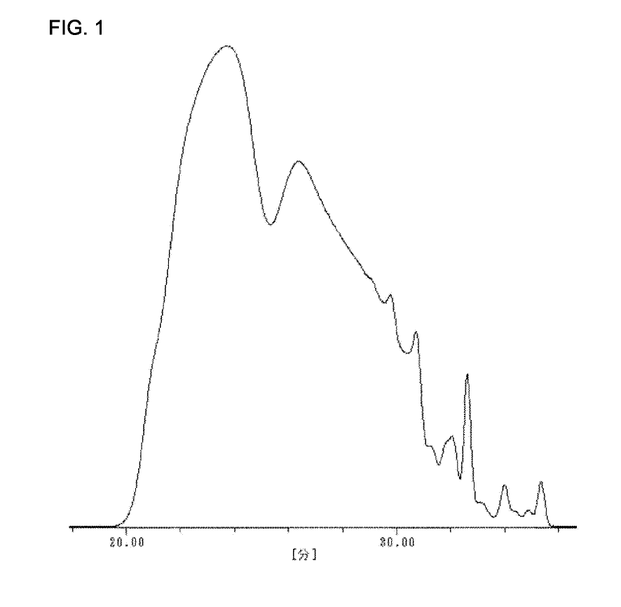

In a 100 ml two-neck flask provided with a condenser, 6.0 g of the novolac phenol resin (C1) produced in Production Example 3 and 1.1 g of ethyl vinyl ether were charged and dissolved in 30 g of 1,3-dioxolane. Then, 0.01 g of a 35 wt % aqueous hydrochloric acid solution was added to the resultant solution and subjected to reaction at 25° C. (room temperature) for 4 hours. After the reaction, 0.1 g of a 25 wt % aqueous ammonia solution was added, and the resultant mixture was poured into 100 g of ion exchange water to precipitate a reaction product. The reaction product was dried at 80° C. and reduced pressure of 1.3 kPa to produce 5.9 g of modified novolac phenol resin (1). FIG. 1 shows a GPC chart of the resultant modified novolac phenol resin (1).

### Example 2

### Production of Modified Novolac Phenol Resin (2)

Excepting that 3.8 g of ethyl vinyl ether was used as a raw material, the same operations as in Example 1 were performed to produce 6.1 g of modified novolac phenol resin (2).

### Example 3

### Production of Modified Novolac Phenol Resin (3)

Excepting that 6.0 g of the novolac phenol resin (C2) produced in Production Example 4 was used as a raw material, the same operations as in Example 1 were performed to produce 5.8 g of modified novolac phenol resin (3).

### Example 4

### Production of Modified Novolac Phenol Resin (4)

Excepting that 6.0 g of the novolac phenol resin (C2) produced in Production Example 4 was used as a raw material, the same operations as in Example 2 were performed to produce 6.2 g of modified novolac phenol resin (4).

### Example 5

### Production of Modified Novolac Phenol Resin (5)

In a 100 ml two-neck flask provided with a condenser, 6.0 g of the novolac phenol resin (C1) produced in Production Example 3 and 1.3 g of dihydropyran were charged and dissolved in 30 g of 1,3-dioxolane. Then, 0.01 g of a 35 wt % aqueous hydrochloric acid solution was added to the resultant solution and subjected to reaction at 25° C. (room temperature) for 4 hours. After the reaction, 0.1 g of a 25 wt % aqueous ammonia solution was added, and the resultant mixture was poured into 100 g of ion exchange water to precipitate a reaction product. The reaction product was dried at 80° C. and reduced pressure of 1.3 kPa to produce 6.4 g of modified novolac phenol resin (5).

### Example 6

### Production of Modified Novolac Phenol Resin (6)

Excepting that 4.4 g of dihydropyran was used as a raw material, the same operations as in Example 5 were performed to produce 7.6 g of modified novolac phenol resin (6).

### Example 7

### Production of Modified Novolac Phenol Resin (7)

Excepting that 6.0 g of the novolac phenol resin (C2) produced in Production Example 4 was used as a raw material, the same operations as in Example 5 were performed to produce 6.2 g of modified novolac phenol resin (7).

### Example 8

### Production of Modified Novolac Phenol Resin (9)

Excepting that 6.0 g of the novolac phenol resin (C2) produced in Production Example 4 was used as a raw material, the same operations as in Example 6 were performed to produce 8.0 g of novolac phenol resin (D8).

### Comparative Production Example 1

### Production of Novolac Phenol Resin (C′1) for Comparison

In a four-neck flask provided with a stirrer and a thermometer, 648 g (6 mol) of m-cresol, 432 g (4 mol) of p-cresol, 428 g (6 mol) of 42% formaldehyde, and 244 g (2 mol) of salicylaldehyde were charged and dissolved in 2000 g of 2-ethoxyethanol. Then, 10.8 g of p-toluenesulfonic acid monohydrate was added to the resultant solution, heated to 100° C., and subjected to reaction. After the reaction, the resultant solution was re-precipitated with water to produce a crude product. The resultant crude product was re-dissolved in acetone and further re-precipitated with water, and the resultant product was filtered off and dried under vacuum to produce 962 g of light brown powder of novolac phenol resin (C′1) for comparison. The novolac phenol resin (C′1) for comparison had a number-average molecular weight (Mn) of 2,020, a weight-average molecular weight (Mw) of 5,768, and a polydispersity (Mw/Mn) of 2.856.

### Comparative Production Example 2

### Production of Novolac Phenol Resin (C′2) for Comparison

In a four-neck flask provided with a stirrer and a thermometer, 648 g (6 mol) of m-cresol, 432 g (4 mol) of p-cresol, 2.5 g (0.2 mol) of oxalic acid, 492 g of 42% formaldehyde were charged, heated to 100° C., and subjected to reaction. After the reaction, the resultant solution was dehydrated up to 200° C. at normal pressure, distillated, and then distillated under reduced pressure at 230° C. for 6 hours to produce 736 g of novolac phenol resin (C′2) for comparison. The novolac phenol resin (C′2) for comparison had a number-average molecular weight (Mn) of 2,425, a weight-average molecular weight (Mw) of 6,978, and a polydispersity (Mw/Mn) of 2.878.

### Comparative Production Example 3

### Production of Modified Novolac Phenol Resin (1′) for Comparison

Excepting that 6.0 g of the novolac phenol resin (C′1) for comparison produced in Comparative Production Example 1 and 2.5 g ethyl vinyl ether were used as raw materials, the same operations as in Example 1 were performed to produce 6.8 g of modified novolac phenol resin (1′) for comparison.

### Comparative Production Example 4

### Production of Modified Novolac Phenol Resin (2′) for Comparison

Excepting that 6.0 g of the novolac phenol resin (C′2) for comparison produced in Comparative Production Example 2 and 2.5 g ethyl vinyl ether were used as raw materials, the same operations as in Example 1 were performed to produce 7.1 g of modified novolac phenol resin (2′) for comparison.

### Examples 9 to 16 and Comparative Examples 1 and 2

Evaluation tests were performed for each of the modified novolac phenol resins (1) to (8) produced as described above and the modified novolac phenol resins (1′) and (2′) for comparison produced in Comparative Production Examples 3 and 4 by methods described below. The results are shown in Tables 1 and 2.

### Preparation of Photosensitive Composition

The components were mixed at each of the ratios shown in Table 1 or 2 and dissolved, and the resultant solution was filtered with a 0.2 μm membrane filter to prepare each of photosensitive compositions (1) to (8) and photosensitive compositions (1′) and (2′) for comparison.

Photoacid generator: diphenyl(4-methylphenyl)sulfonium trifluoromethanesulfonate (manufactured by Wako Pure Chemical Industries, Ltd., “WPAG-336”)

Solvent: propylene glycol monomethyl ether acetate (PGMEA)

### Evaluation of Alkali Developability

A photosensitive composition was applied on a 5-inch silicon wafer by using a spin coater so that the thickness was about 1 μm, and dried on a hot plate of 110° C. for 60 seconds. In this way, two wafers were prepared, one of the wafers was used as an “unexposed sample”, and the other was irradiated with ghi line of 100 mJ/cm² by using a ghi line lamp (manufactured by Ushio Inc., “Multilight”), heat-treated under the conditions of 140° C. and 60 seconds, and used as an “exposed sample”.

Both the “unexposed sample” and the “exposed sample” were immersed in an alkali developer (2.38% aqueous tetramethylammonium hydroxide solution) for 60 seconds and then dried on a hot plate of 110° C. for 60 seconds. The thickness was measured before and after immersion in the developer, and a value obtained by dividing a difference in thickness by 60 was as regarded as alkali developability [ADR (Å/s)].

### Method for Evaluating Photosensitivity

A photosensitive composition was applied on a 5-inch silicon wafer by using a spin coater so that the thickness was about 1 μm, and dried on a hot plate of 110° C. for 60 seconds. A mask corresponding to a resist pattern having a line-and-space of 1:1 and line widths of 1 to 10 μm at intervals of 1 μm was adhered to the wafer, irradiated with ghi line of 100 mJ/cm² by using a ghi line lamp (manufactured by Ushio Inc., “Multilight”), and heat-treated under the conditions of 140° C. and 60 seconds. Then, the wafer was immersed in an alkali developer (2.38% aqueous tetramethylammonium hydroxide solution) for 60 seconds and then dried on a hot plate of 110° C. for 60 seconds.

An amount of ghi line exposure was increased from 30 mJ/cm² at intervals of 5 mJ/cm², and an amount of exposure (Eop exposure amount) with which a line width of 3 μm can be faithfully realized was evaluated.

### Method for Evaluating Heat Resistance

A photosensitive composition was applied on a 5-inch silicon wafer by using a spin coater so that the thickness was about 1 μm, and dried on a hot plate of 110° C. for 60 seconds. The resin content was scraped out from the resultant wafer, and the glass transition temperature (Tg) of the resin was measured. The glass transition temperature (Tg) was measured by using a differential scanning calorimeter (manufactured by TA Instruments Co., Ltd., differential scanning calorimeter (DSC) Q100) in a nitrogen atmosphere under the conditions of a temperature range of −100° C. to 200° C. and a heating temperature of 10° C./min.

TABLE 1

| | | | Example | Example | Example | Example | Example | Example | Example |
|---|---|---|---|---|---|---|---|---|---|
| | | Example 9 | 10 | 11 | 12 | 13 | 14 | 15 | 16 |
| Modified novolac phenol | | 19 | | | | | | | |
| resin (1) [parts by mass] | | | | | | | | | |
| Modified novolac phenol | | | 19 | | | | | | |
| resin (2) [parts by mass] | | | | | | | | | |
| Modified novolac phenol | | | | 19 | | | | | |
| resin (3) [parts by mass] | | | | | | | | | |
| Modified novolac phenol | | | | | 19 | | | | |
| resin (4) [parts by mass] | | | | | | | | | |
| Modified novolac phenol | | | | | | 19 | | | |
| resin (5) [parts by mass] | | | | | | | | | |
| Modified novolac phenol | | | | | | | 19 | | |
| resin (6) [parts by mass] | | | | | | | | | |
| Modified novolac phenol | | | | | | | | 19 | |
| resin (7) [parts by mass] | | | | | | | | | |
| Modified novolac phenol | | | | | | | | | 19 |
| resin (8) [parts by mass] | | | | | | | | | |
| Photosensitizer ([PAG-336]) | | 1 | 1 | 1 | 1 | 1 | 1 | 1 | 1 |
| [parts by mass] | | | | | | | | | |
| PGMEA [parts by mass] | | 80 | 80 | 80 | 80 | 80 | 80 | 80 | 80 |
| Presence ratio of phenolic | | 83/17 | 27/73 | 76/24 | 35/65 | 84/16 | 65/35 | 77/23 | 70/30 |
| hydroxyl group (α) to acid | | | | | | | | | |
| dissociable group (β) | | | | | | | | | |
| [(α)/(β)] | | | | | | | | | |
| Evaluation of | [Unexposed | 0 | 0 | 0 | 0 | 0 | 0 | 0 | 0 |
| alkali | sample] | | | | | | | | |
| developability | [Exposed | 520 | 350 | 470 | 260 | 490 | 340 | 450 | 320 |
| [Å/s] | sample] | | | | | | | | |

| | | | | | | | | |
|---|---|---|---|---|---|---|---|---|
| Evaluation of | 25 | 25 | 25 | 25 | 20 | 20 | 20 | 20 |
| photosensitivity [mJ/cm²] | | | | | | | | |
| Evaluation of heat | 187 | 156 | 174 | 152 | 175 | 152 | 165 | 152 |
| resistance [° C.] | | | | | | | | |

TABLE 2

| | | Compar- | Compar- |
|---|---|---|---|
| | | ative | ative |
| | | Example 1 | Example 2 |
| Modified novolac phenol resin for comparison (1′) | | 19 | |
| [parts by mass] | | | |
| Modified novolac phenol resin for comparison (2′) | | | 19 |
| [parts by mass] | | | |
| Photosensitizer ([PAG-336]) [parts by mass] | | 1 | 1 |
| PGMEA [parts by mass] | | 80 | 80 |
| Presence ratio of phenolic hydroxyl group (α) | | 55/45 | 53/47 |
| to acid dissociable group (β) | | | |
| [(α)/(β)] | | | |
| Evaluation of alkali | [Unexposed sample] | 0 | 0 |
| developability [Å/s] | [Exposed sample] | 280 | 110 |

| | | |
|---|---|---|
| Evaluation of photosensitivity [mJ/cm²] | 25 | 75 |
| Evaluation of heat resistance [° C.] | 113 | 52 |

1. A modified novolac phenol resin having a molecular structure in which hydrogen atoms of phenolic hydroxyl groups possessed by a novolac phenol resin (C) are partially or entirely substituted by acid dissociable groups, the novolac phenol resin (C) being produced by condensing an aromatic compound (A) represented by structural formula (1) below with an aldehyde compound (B), 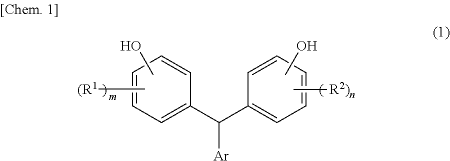
[in the formula, Ar is a structural moiety represented by structural formula (2-1) or (2-2) below 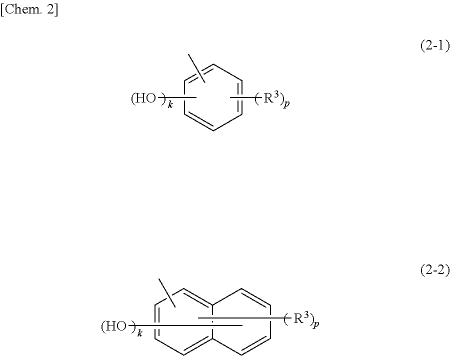
(in the formula, k is an integer of 0 to 2, p is an integer of 1 to 5, q is an integer of 1 to 7, and R³ is any one of a hydrogen atom, an alkyl group, an alkoxy group, an aryl group, an aralkyl group, and a halogen atom), R¹ and R² are each any one of an alkyl group, an alkoxy group, an aryl group, an aralkyl group, and a halogen atom, and m and n are each an integer of 1 to 4].

2. The modified novolac phenol resin according to claim 1, wherein the acid dissociable group is any one of a tertiary alkyl group, an alkoxyalkyl group, an acyl group, an alkoxycarbonyl group, a heteroatom-containing cyclic hydrocarbon group, and a trialkylsilyl group.

3. The modified novolac phenol resin according to claim 2, wherein the acid dissociable group is any one of an alkoxyalkyl group, an alkoxycarbonyl group, and a heteroatom-containing cyclic hydrocarbon group.

4. The modified novolac phenol resin according to claim 1, wherein a presence ratio [(α)/(β)] of phenolic hydroxyl group (α) to acid dissociable group (β) in the resin is within a range of 95/5 to 10/90.

5. The modified novolac phenol resin according to claim 1, produced by reacting a phenol compound (a1) having any one of an alkyl group, an alkoxy group, an aryl group, an aralkyl group, and a halogen atom as a substituent on an aromatic nucleus with an aromatic aldehyde (a2) to produce an aromatic compound (A), condensation-reacting the resultant aromatic compound (A) with an aldehyde compound (B), and then reacting the resultant novolac phenol resin (C) with a compound represented by any one of structural formulae (3-1) to (3-8) 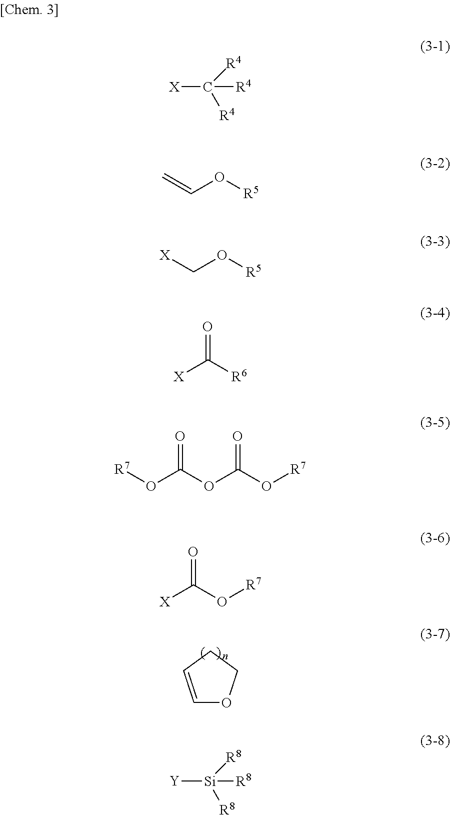
(in the formulae, X represents a halogen atom, Y represents a halogen atom or a trifluoromethanesulfonyl group, R⁴ to R⁸ each independently represent an alkyl group having 1 to 6 carbon atoms or a phenyl group, and n is 1 or 2).

6. A method for producing a modified novolac phenol resin, the method comprising reacting a phenol compound (a1) having any one of an alkyl group, an alkoxy group, an aryl group, an aralkyl group, and a halogen atom as a substituent on an aromatic nucleus with an aromatic aldehyde (a2) to produce an aromatic compound (A), condensation-reacting the resultant aromatic compound (A) with an aldehyde compound (B), and then reacting the resultant novolac phenol resin (C) with a compound represented by any one of structural formulae (3-1) to (3-8) 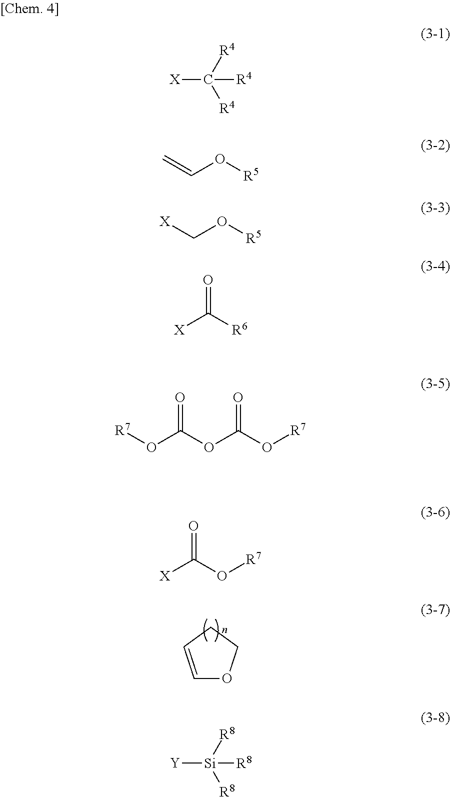
(in the formulae, X represents a halogen atom, Y represents a halogen atom or a trifluoromethanesulfonyl group, R⁴ to R⁸ each independently represent an alkyl group having 1 to 6 carbon atoms or a phenyl group, and n is 1 or 2).

7. A photosensitive composition comprising the modified novolac phenol resin according to claim 1 and a photoacid generator.

8. A resist material comprising the photosensitive composition according to claim 7.

9. A coating film comprising the photosensitive composition according to claim 7.

10. A resist permanent film comprising the resist material according to claim 8.
